(19) United States
(12) Patent Application Publication
(10) Pub. No.: US 2015/0077963 A1
(43) Pub. Date: Mar. 19, 2015

(54) PRINTED WIRING BOARD WITH METAL POST AND METHOD FOR MANUFACTURING PRINTED WIRING BOARD WITH METAL POST

(71) Applicant: IBIDEN CO., LTD., Ogaki-shi (JP)

(72) Inventors: Takema ADACHI, Ogaki-shi (JP); Yuzo KAIDA, Ogaki-shi (JP)

(73) Assignee: IBIDEN CO., LTD., Ogaki-shi (JP)

(21) Appl. No.: 14/491,069

(22) Filed: Sep. 19, 2014

(30) Foreign Application Priority Data
Sep. 19, 2013 (JP) 2013-193646

(51) Int. Cl. H05K 1/14; H05K 3/42; H05K 3/36; H05K 3/10; H05K 1/11; H05K 3/00

(52) U.S. Cl. CPC H05K 1/141; H05K 1/11; H05K 3/0073; H05K 3/36; H05K 3/10; H05K 3/42; H05K 2201/042
USPC 361/803; 174/255; 29/847; 29/830

(57) ABSTRACT

A printed wiring board includes a wiring board, and multiple posts formed on the wiring board and positioned to mount a second printed wiring board onto the wiring board. Each of the metal posts has a first surface connected to the wiring board, a second surface formed to connect the second printed wiring board, and a side surface between the first surface and the second surface, and the side surface of each of the metal posts forms a curved surface.

### CROSS-REFERENCE TO RELATED APPLICATIONS

The present application is based upon and claims the benefit of priority to Japanese Patent Application No. 2013-193646, filed Sep. 19, 2013, the entire contents of which are incorporated herein by reference.

### BACKGROUND OF THE INVENTION

1. Field of the Invention

The present invention relates to a first printed wiring board that has a metal post for mounting a second printed wiring board, a printed wiring board that has a metal post, a printed wiring board that is formed by the first printed wiring board and the second printed wiring board, and methods for manufacturing these printed wiring boards.

2. Description of Background Art

Japanese Patent Laid-Open Publication No. 2012-23364 describes a metal post formed on a base substrate. The entire contents of this publication are incorporated herein by reference.

### SUMMARY OF THE INVENTION

According to one aspect of the present invention, a printed wiring board includes a wiring board, and multiple posts formed on the wiring board and positioned to mount a second printed wiring board onto the wiring board. Each of the metal posts has a first surface connected to the wiring board, a second surface formed to connect the second printed wiring board, and a side surface between the first surface and the second surface, and the side surface of each of the metal posts forms a curved surface.

According to yet another aspect of the present invention, a method for manufacturing a printed wiring board includes forming a metal layer on a support film, forming an etching mask on the metal layer, etching a portion of the metal layer exposed from the etching mask such that the portion of the metal layer is removed and multiple metal posts each having a curved side surface is formed, removing the etching mask remaining on the metal posts, removing the support film from the metal posts, and mounting the metal posts on a wiring board such that the metal posts are positioned to mount a second printed wiring board onto the wiring board.

According to another aspect of the present invention, a method for manufacturing a printed wiring board includes forming a seed layer on a wiring board, forming an electrolytic plating layer on the seed layer, forming an etching mask on the electrolytic plating layer, and etching a portion of the electrolytic plating layer exposed from the etching mask such that the portion of the electrolytic plating layer is removed and multiple metal posts each having a curved side surface is formed on the wiring board such that the metal posts are positioned to mount a second printed wiring board onto the wiring board.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 illustrates a cross-sectional view of an application example of a printed wiring board according to a first embodiment of the present invention.

FIG. 2 illustrates a cross-sectional view of a wiring board of the first embodiment.

FIG. 3 illustrates a cross-sectional view of a second printed wiring board

FIG. 4A illustrates a cross-sectional view of a first printed wiring board of the first embodiment; and FIGS. 4B and 4C illustrate examples of a metal post.

FIG. 5A illustrates a plan view of a mounting surface; and FIG. 5B illustrates a mounting surface that has metal posts.

FIG. 6A-6F illustrate manufacturing process diagrams of a metal post according to the first embodiment.

FIG. 7A-7C illustrate manufacturing process diagrams of the first printed wiring board.

FIG. 8 illustrates a cross-sectional view of an application example of a printed wiring board according to the first embodiment.

FIG. 9 illustrates a cross-sectional view of an application example of a printed wiring board according to a second embodiment of the present invention.

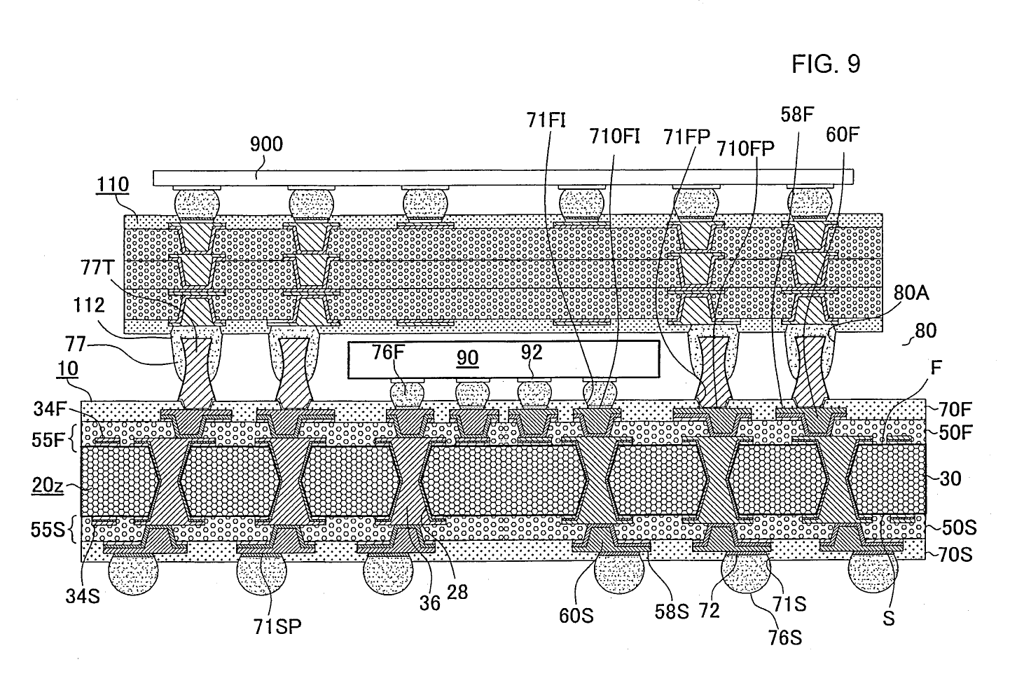

FIG. 10 illustrates a cross-sectional view of a wiring board of the second embodiment.

FIG. 11A illustrates a cross-sectional view of a first printed wiring board of the second embodiment; and FIG. 11B illustrates a cross-sectional view of a metal post.

FIGS. 12A and 12B illustrate manufacturing process diagrams of a metal post according to the second embodiment.

FIGS. 13A and 13B illustrate manufacturing process diagrams of a metal post according to the second embodiment.

FIGS. 14A and 14B illustrate manufacturing process diagrams of a metal post according to the second embodiment.

FIG. 15A-15D illustrate schematic diagrams of metal posts.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

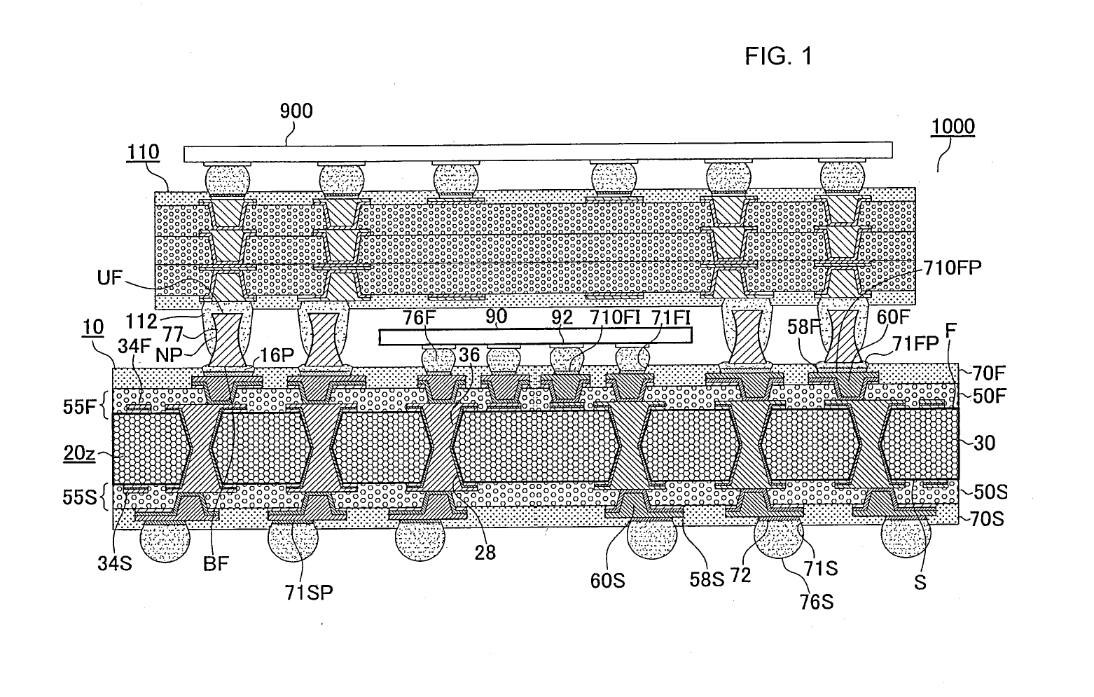

An application example of a printed wiring board 1000 according to a first embodiment of the present invention is illustrated in FIG. 1. The printed wiring board 1000 is formed by a first printed wiring board (lower substrate) 10 and a second printed wiring board (upper substrate) 110 that is mounted on the first printed wiring board.

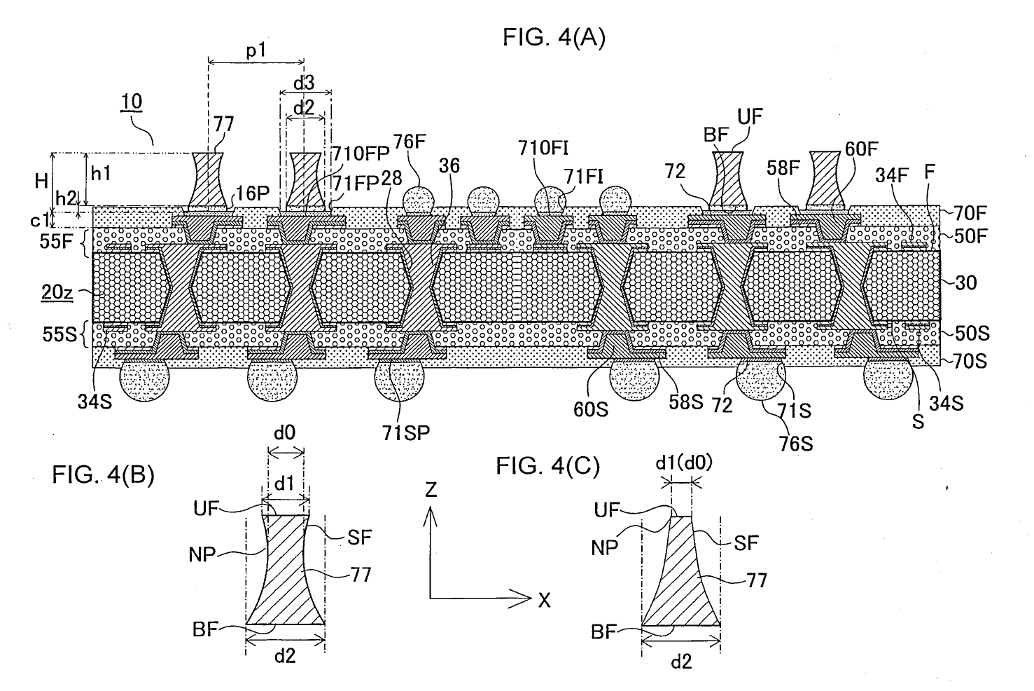

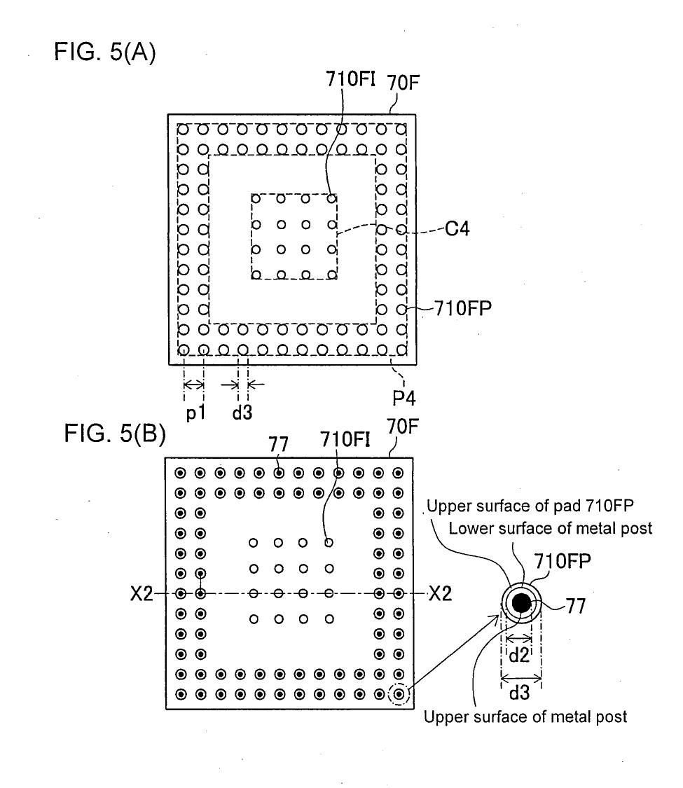

The first printed wiring board 10 has a pad (first pad) (710FI) for mounting an electronic part 90 such as an IC chip and a pad (second pad) (710FP) for mounting the second printed wiring board (upper substrate) 110. An electronic part 900 such as a memory is mounted on the second printed wiring board. Pads (710FI) form a pad group C4 (see FIG. 5A). The pad group C4 is formed substantially at a center of the printed wiring board 10. The pad 710FP is formed in an outer periphery region P4 (see FIG. 5A) around the pad group C4. A joining post (metal post) 77 for mounting the upper substrate is formed on the pad (710FP). As illustrated in FIGS. 4A and 4C, the metal post has an upper surface (UF), a lower surface (BF) that is on an opposite side of the upper surface, and a side surface SF between the upper surface and the lower surface. The side surface is curved. It is preferable that a diameter of the metal post at the upper surface is smaller than a diameter of the metal post at the lower surface. In FIG. 4B, a thinnest portion (NP) exists between the upper surface and the lower surface, and a diameter of the thinnest portion is smaller than the diameter at the upper surface and is smaller than the diameter at the lower surface. In FIG. 4C, the diameter of the metal post increases from the upper surface to the lower surface. In FIG. 4C, the thinnest portion NP is formed at the upper surface of the metal post. A shape of the side surface of the metal post is not straight but curved. Therefore, a stress caused by a difference in physical properties between the first printed wiring board and the second printed wiring board is relaxed by the metal post. Examples of physical properties include thermal expansion coefficient, Young's modulus, and the like. The metal post of FIG. 4B is more suitable for stress relaxation than the metal post of the FIG. 4C.

The metal post 77 has a function of electrically connecting the first printed wiring board 10 and the second printed wiring board 110. Further, even when a pitch p1 between adjacent pads (710FP) is 0.3 mm or less, a distance between the first printed wiring board (lower substrate) 10 and the second printed wiring board (upper substrate) 110 is ensured by the metal post 77. Even when the pitch (p1) between adjacent pads (710FP) is 0.25 mm or less, a distance between the first printed wiring board 10 and the second printed wiring board (upper substrate) 110 is kept constant by the metal post 77. Insulation between adjacent pads is ensured. The pitch (p1) is a distance between centers of the adjacent pads (710FP). Or, the pitch p1 is a distance between centroids of the adjacent pads (710FP) (see FIGS. 4A and 5A). A pitch between adjacent metal posts and the pitch between adjacent pads are substantially the same.

The first printed wiring board 10 may be a printed wiring board having a core substrate, or may be a coreless substrate. A printed wiring board having a core substrate and a manufacturing method thereof are described, for example, in JP2007227512A. The entire contents of this publication are incorporated herein by reference. A coreless substrate and a manufacturing method thereof are described, for example, in JP2005236244A. The coreless substrate has resin insulating layers and conductor layers that are alternately laminated. All the resin insulating layers have a thickness of, for example, 60 μm or less.

As illustrated in FIG. 4A, the first printed wiring board 10 has a core substrate 30. The core substrate has an insulating substrate (20z) that has a first surface (F) and a second surface (S) that is on an opposite side of the first surface; a first conductor layer (34F) that is formed on the first surface (F) of the insulating substrate; and a second conductor layer (34S) that is formed on the second surface of the insulating substrate. The core substrate further has a through-hole conductor 36 that fills a through hole 28 for the through-hole conductor with a plating film, the through hole 28 being formed in the insulating substrate (20z). The through-hole conductor 36 connects the first conductor layer (34F) and the second conductor layer (34S). A first surface of the core substrate and the first surface of the insulating substrate are the same surface; and a second surface of the core substrate and the second surface of the insulating substrate are the same surface.

On the first surface (F) of the core substrate 30, an interlayer resin insulating layer (uppermost interlayer resin insulating layer) (50F) is formed. On the interlayer resin insulating layer (50F), a conductor layer (uppermost conductor layer) (58F) is formed. The conductor layer (58F), the first conductor layer (34F) and the through-hole conductor are connected by a via conductor (uppermost via conductor) (60F) that penetrates through the interlayer resin insulating layer (50F). An upper side build-up layer (55F) is formed by the interlayer resin insulating layer (50F), the conductor layer (58F) and the via conductor (60F). In the first embodiment, the upper side build-up layer is a single layer. The uppermost conductor layer has the pads (710FI, 710FP). The first pad (710FI) and the second pad (710FP) are an upper surface of a conductor circuit contained in the uppermost conductor layer and an upper surface of the uppermost via conductor.

On the second surface (S) of the core substrate 30, an interlayer resin insulating layer (lowermost interlayer resin insulating layer) (50S) is formed. On the interlayer resin insulating layer (50S), a conductor layer (lowermost conductor layer) (58S). The conductor layer (58S), the second conductor layer (34S) and the through-hole conductor are connected by a via conductor (lowermost via conductor) (60S) that penetrates the interlayer resin insulating layer (505). A lower side build-up layer (55S) is formed by the interlayer resin insulating layer (50S), the conductor layer (58S) and the via conductor (60S). In the first embodiment, the lower side build-up layer is a single layer. The lowermost conductor layer has a BGA pad (71SP) for connecting to a motherboard. The pad (71SP) is an upper surface of a conductor circuit contained in the lowermost conductor layer and an upper surface of the lowermost via conductor.

An upper side solder resist layer (70F) is formed on the upper side build-up layer, and a lower side solder resist layer (70S) is formed on the lower side build-up layer. The solder resist layer (70F) has an opening (first opening) (71FI) for exposing the pad (710FI) and an opening (second opening) (71FP) for exposing the pad (710FP). The solder resist layer (70S) has an opening (71S) for exposing the BGA pad (71SP). Connection members (76F, 76S) such as a solder bump and a Sn film for connecting an electronic part and a motherboard are formed on the pad (710FI) and the BGA pad (71SP). A solder bump (first joining member) (760F) is formed on the pad (710FP). The metal post 77 is mounted on the pad (710FP) via the first joining member (first solder). It is also possible that there is not a connection member.

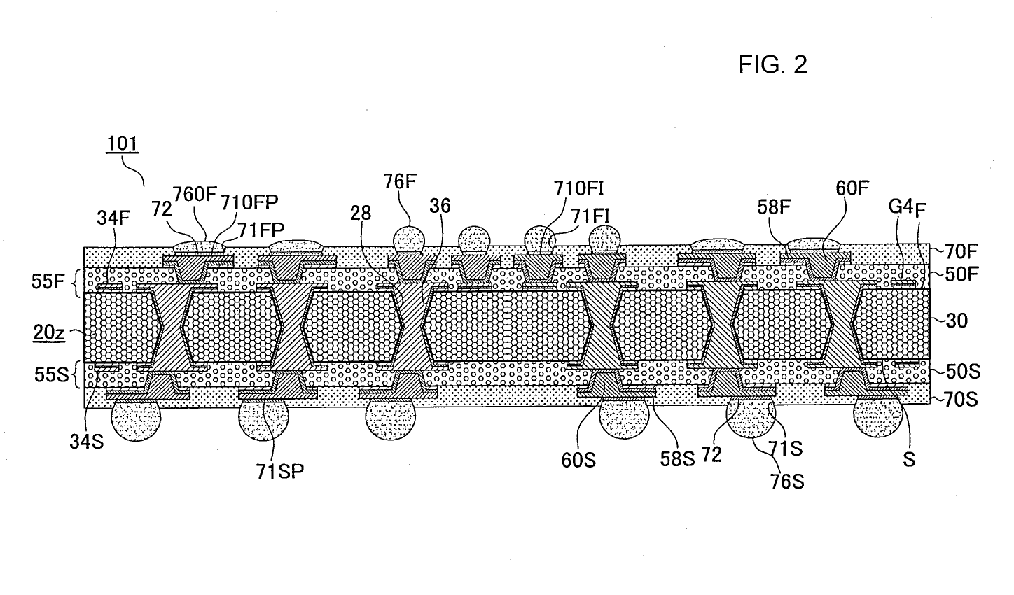

FIG. 2 illustrates a cross-sectional view of a wiring board 101 that has the connection members (76F, 76S). FIG. 5A illustrates a mounting surface of a first printed wiring board. The mounting surface has the upper side solder resist layer (70F) and the pads (710FI, 710FP). The metal post is connected on the pad (710FP). A reference numeral symbol (d3) indicates a diameter of the pad (710FP). The upper surface of the metal post 77, the solder resist layer (70F) and the pads (710FI, 710FP) are illustrated in FIG. 5B.

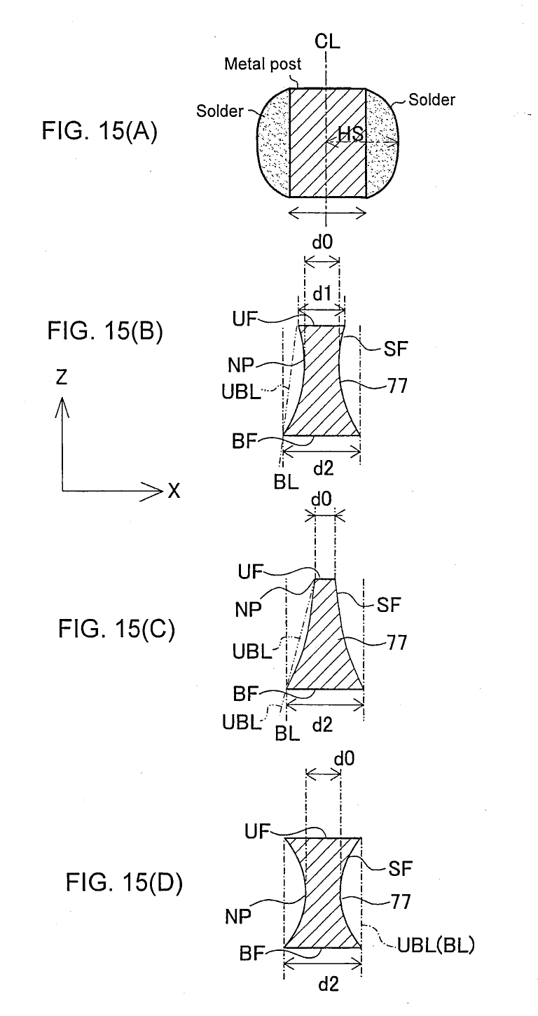

The metal post 77 has the upper surface (UF) and the lower surface (BF) on the opposite side of the upper surface. Further, the metal post 77 has the side surface (SF) between the upper surface and the lower surface. The lower surface of the metal post opposes the pad (710FP). A cross section of the first printed wiring board 10 along line X2-X2 in FIG. 5B is illustrated in FIG. 4A. The metal post 77 is formed on the pad (710FP) via a first joining member (16P) such as a solder or a Sn film. The pad (710FP) and the metal post 77 are joined by the first joining member (16P). The metal posts 77 illustrated in FIGS. 4B, 15B and 15D each have a constricted portion on the side surface. A diameter (d2) of the lower surface (BF) of the metal post is 50 μm-200 μm. A diameter (d1) of the upper surface may be the same as the diameter (d2) of the lower surface. However, it is desirable that the diameter (d1) of the upper surface is smaller than the diameter of the lower surface by 10 μm-50 μm. The diameter of the upper surface is 30 μm-180 μm. A diameter (d0) of the thinnest portion (NP) is smaller than the diameter of the upper surface by 10 μm-30 μm. The diameter (d0) the thinnest portion (NP) is 20 μm-160 μm.

The diameter (d3) of the pad (710FP) is 55 μm-210 μm. The diameter of the pad is a diameter of a conductor (the conductor circuit and the via conductor) that is exposed through the opening of the solder resist layer. The diameter (d2) of the metal post 77 (the diameter of the lower surface of the metal post) is smaller than the diameter (d3). It is preferable that a ratio (d2/d3) between the diameter (d2) of the metal post and the diameter (d3) of the pad is in a range from 0.5 to 0.9. The pitch between the pads can be reduced. Even when the pitch (p1) is 0.3 mm or less, connection reliability between the lower substrate 10 and the upper substrate is high. Further, insulation reliability between the metal posts is high. The distance (pitch) (p1) between the adjacent pads (710FP) is 100 μm-300 μm. When the pitch (p1) is less than 100 μm, the insulation reliability between the metal posts is likely to decrease. Further, since the thin portion (NP) of the metal post becomes thinner, the connection reliability between the upper substrate and the lower substrate 10 decreases. When the pitch (p1) exceeds 300 μm, a size of the printed wiring board 10 increases. Therefore, since stress acting on the metal post is increased, cracking is likely to occur in the thin portion (NP) of the metal post in a heat cycle.

When the pitch (p1) is 0.3 mm or less, a height (distance from the upper surface to the lower surface) (h1) of the metal post 77 is 75 μm-200 μm; the diameter (d2) of the metal post is 75 μm-200 μm; and a thickness (h2) of the first joining member (16P) such as a solder layer is 10-30 μm. The connection reliability between the lower substrate and the upper substrate and the insulation reliability between metal posts are improved.

When the pitch (p1) is 0.25 mm or less, the height (h1) of the metal post 77 is 75 μm-150 μm; the diameter (d2) of the metal post is 50 μm-150 μm; and the thickness (h2) of the first joining member (16P) such as a solder layer is 10-20 μm. The connection reliability between the lower substrate and the upper substrate and the insulation reliability between metal posts are improved.

It is preferable that an aspect ratio (the height h1/the diameter d0) R1 of the metal post is 1 or more. When the metal post has the thin portion (NP) and the aspect ratio (R1) is 1 or more, the stress between the upper substrate and the lower substrate is relaxed by the metal post. The connection reliability is increased. It is preferable that the aspect ratio (h1/d0) R1 is 1.5-3. The stress between the upper substrate and the lower substrate is relaxed. Further, the metal post does not deteriorate due to fatigue. The connection reliability between the upper substrate and the first printed wiring board 10.

It is preferable that an aspect ratio (the diameter d2 of the lower surface BF/the diameter d0 of the thinnest portion NP) R2 of the metal post is 1.2 or more. A stress caused by a difference between a physical property value of the upper substrate and a physical property value of the lower substrate is relaxed by the thin portion (NP). The connection reliability between the upper substrate and the lower substrate is increased. It is preferable that the aspect ratio (R2) is less than 3.8. When the aspect ratio (R2) exceeds 3.8, the thinnest portion is likely to deteriorate in a heat cycle.

When the thickness (h2) of the first joining member (16P) is less than a predetermined value, the metal post 77 comes off from the pad (710FP). When the thickness (h2) of the first joining member (16P) is more than a predetermined value, short-circuiting is likely to occur between the metal posts due to the joining member.

As illustrated in FIGS. 4B, 4C and 15B-15D, the side surface of the metal post is curved. It is preferable that the diameter d1 of the upper surface of the metal post is smaller than the diameter (d2) of the lower surface. With respect to alignment, a tolerance between the upper substrate and the metal post is increased. The metal post and the upper substrate are surely connected. Therefore, the connection reliability between the upper substrate and the metal post is increased. Since the metal post has the thin portion (NP), the metal post can be easily deformed. The stress between the upper substrate 110 and the lower substrate 10 is relaxed. Even when the pitch (p1) between the pads (710FP) is 0.3 mm or less, the connection reliability between the lower substrate and the upper substrate is not decreased.

A Z-axis and an X-axis are illustrated in FIGS. 4A-4C and 15A-15D. As illustrated in the figures, the Z-axis is perpendicular to the first surface of the core substrate. As illustrated in the figures, the X-axis is parallel to the first surface of the core substrate. The metal post cross-sectional views that are illustrated in FIG. 15A-15D are each obtained by cutting a metal post along a plane that is perpendicular to the first surface of the core substrate and contains an axis of the metal post. Further, the axis of the metal post is a straight line that passes through a centroid or a center of the lower surface of the metal post and is perpendicular to the first surface of the core substrate. In FIG. 4A-4C, the lower surface of the metal post is mounted parallel to the first surface of the core substrate.

The metal post and the lower substrate, and the metal post and the upper substrate, are connected by joining members such as a solder. Reflow is generally used. When a solder is melted, the solder wetly spreads to the side surface of the metal post. In this case, as illustrated in FIG. 15A, the solder expands in the X-axis direction. The side surface of the metal post illustrated in FIG. 15A is straight. The side surfaces of the metal posts illustrated in FIG. 15B-15D are curved. The metal posts illustrated in FIGS. 15B and 15D each have a thinnest portion (NP) between the upper surface and the lower surface. The diameter of each of the metal posts illustrated in FIGS. 15C and 4C becomes larger from the upper surface toward the lower surface of the metal post. In FIG. 15A-15D, the pitches between metal posts, the diameters of the lower surfaces of the metal posts and the heights of the metal posts are respectively the same. Further, volumes of solders formed on the metal posts are the same.

In the following, a height (HS) of a second joining member such as a solder (second solder) is described with reference to FIG. 15A. The metal post and the upper substrate are connected by the second joining member. As illustrated in FIG. 15A, the height (HS) of the solder is a distance between an axis (CL) of the metal post and a top of the second joining member that is formed on the side surface of the metal post. In FIG. 15B-15D, the second joining member is omitted.

The side surface of the metal post in each of FIG. 15B-15D is curved and thus a length of the side surface of the metal post in each of FIG. 15B-15D is longer than a length of the side surface of the metal post in FIG. 15A. In FIG. 15B-15D, a length over which the solder spreads is long. Therefore, in FIG. 15B-15D, the height (HS) of the solder in the X-axis direction is small.

Further, in FIGS. 15B and 4B, the diameter of the upper surface of the metal post is smaller than the diameter of the lower surface, and the side surface of the metal post is inwardly curved. The side surface of the metal post illustrated in each of FIG. 15B-15D is recessed from a line (UBL). The line (UBL) is a straight line passing through an outer circumference of the upper surface of the metal post and an outer circumference of the lower surface of the metal post. The side surface in each of FIGS. 15B and 15C, except a lower end, is positioned in an inner side of a straight line (BL). The straight line (BL) is a straight line passing the outer circumference of the lower surface of the metal post and perpendicular to the first surface of the core substrate. The side surface of the metal post is positioned between the straight line (UBL) and the axis (CL). The side surface of the metal post is positioned between the straight line (BL) and the axis (CL). Therefore, even when the pitch (p1) is the same, for adjacent metal posts, a distance between the side surfaces of the metal posts illustrated in each of FIG. 15B-15D is larger than a distance between the side surfaces of the metal posts illustrated in FIG. 15A. Therefore, for adjacent metal posts, a distanced between the joining members that are formed on the side surfaces of the metal post is longer. Therefore, according to the embodiment, the insulation reliability between the metal posts is high.

For the metal post illustrated in FIG. 15D, the diameter of the upper surface and the diameter of the lower surface are the same, and the thinnest portion (NP) is between the upper surface and the lower surface. The metal post illustrated in FIG. 15D has the same effect as the metal post illustrated in FIG. 15B. However, since the solder is likely to gather on the upper surface side, the height (HS) of the joining member on the side surface of the metal post of FIG. 15B is likely to be lower than the height (HS) of the joining member on the side surface of the metal post of FIG. 15D.

When the metal post and the lower substrate, and the metal post and the upper substrate, are connected by the joining members such as a solder, it is preferable that a metal film such as a gold or Sn film is formed on the side surface of the metal post. The joining member connecting the metal post and the upper substrate is the second joining member. A main component of the metal post is copper. Wettability of a solder with respect to a metal film is higher than wettability of the solder with respect to copper. Therefore, when a metal film is formed on a side surface of a metal post, a solder wetly spreads on the side surface of the metal post. Therefore, the solder does not gather at a particular place. The height (HS) is lowered. Further, due to the metal film, oxidation of the metal post is suppressed. Durability of the metal post is increased.

It is preferable that a ratio (H/c1) between a distance (H) from the upper surface of the pad (710FP) to the upper surface of the metal post and a thickness c1 of the pad (710FP) is 5 or more and 30 or less. When a protective film 72 is formed on the conductor that is exposed from the opening of the solder resist layer, the pad includes the protective film 72. Therefore, in FIG. 4A-4C, the thickness (c1) of the pad is a distance from an upper surface of the interlayer resin insulating layer (50F) to an upper surface of the protective film 72. The protective film 72 is a film for preventing oxidation of the pad. Examples of the protective film include Ni/Au, Ni/Pd/Au, Sn, OSP, and the like. As the metal film that is formed on the side surface of the metal post, a material same as the protective film can be used. When the metal film and the protective film are the same, connection reliability between the metal post and the pad (710FP) is improved. When the metal film and the protective film are different, various metals diffuse from the metal film and the protective film into the joining member that connects the metal post and the pad (710FP). Since various alloys are formed, durability of the first joining member such as the first solder deteriorates.

When the pitch (p1) is 0.3 mm or less, it is preferable that a value of (H/c1) is 7 or more and 25 or less.

Since the pad (710FP) is a base of the metal post, when (H/c1) is too large, the metal post may come off from the pad and reliability of the metal post is reduced. When (H/c1) is too small, it is difficult to relax a stress by the metal post. The connection reliability is decreased.

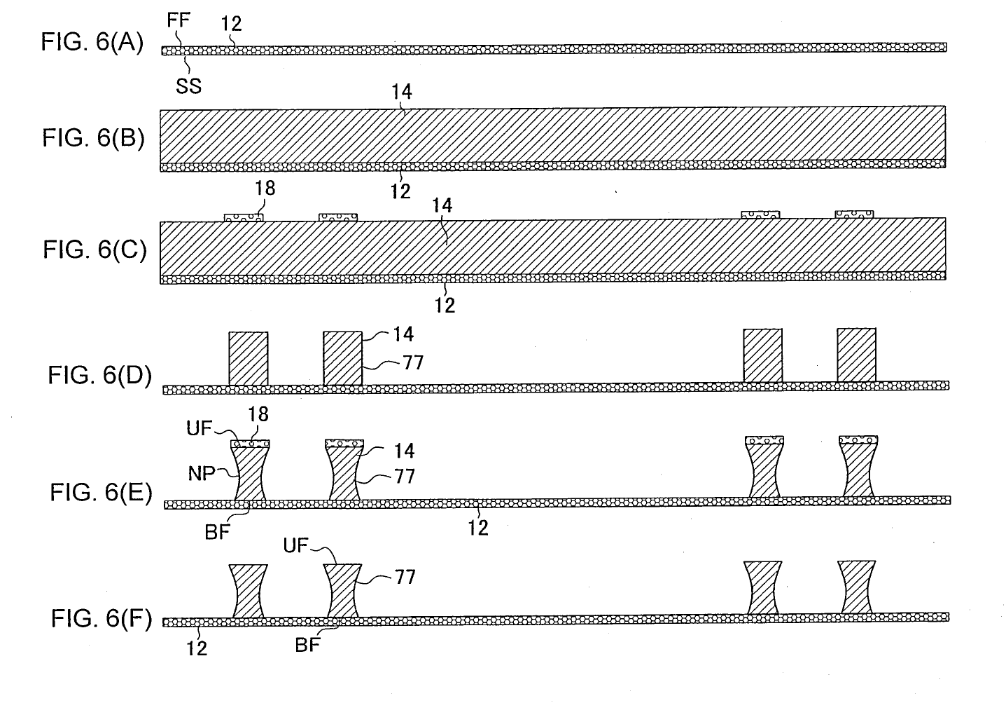

The metal post is manufactured by etching a metal foil. A support film 12 having a first surface (FF) and a second surface (SS) that is on an opposite side of the first surface is prepared (FIG. 6A). A bonding layer is formed on the first surface of the support film. The bonding layer is not illustrated in the drawings. A metal foil 14 such as a copper foil is bonded to the first surface of the support film (FIG. 6B). Next, an etching mask 18 such as an etching resist is formed on the metal foil (FIG. 6C). Thereafter, the metal foil that is partially covered by the etching resist is immersed in an etching solution. The etching solution is, for example, a cupric chloride etching solution. The metal foil that is exposed from the etching resist is removed, and the metal post 77 is formed (FIG. 6E). In this case, since the etching proceeds from the etching resist side toward the support film, the side surface of the metal post is curved. The diameter of the metal post under the etching resist is smaller than the diameter of the metal post on the support film. When the etching is performed by immersion, for a portion of the metal foil that is bonded to the etching resist, etching is inhibited by the etching resist. Therefore, the thinnest portion (NP) between the upper surface (UF) and the lower surface (BF) of the metal post is formed. The etching resist is removed (FIG. 6F). As a result, the metal post 77 having the upper surface (UF) and the lower surface (BF) that is on an opposite side of the upper surface (UF) is formed on the support film. The lower surface of the metal post is bonded to the support film. The support film is removed. The metal post having the shape illustrated in FIG. 4B is manufactured. The metal post having the shape illustrated in FIG. 4B can also be manufactured by spraying an etching solution to a metal layer such as a metal foil using a nozzle that is described in JP2002256458A.

A method for manufacturing another metal post is described below. In a manner similar to the method described above, a metal foil is bonded on a support film (FIG. 6B). Next, an etching resist 18 is formed on the metal foil (FIG. 6C). Thereafter, by spraying an etching solution to the metal foil, the metal foil that is exposed from the etching resist is removed. For example, as the etching solution, an etching solution described in U.S. Pat. No. 7,357,879B2 can be used. The entire contents of this publication are incorporated herein by reference. As the etching method, an etching method using a 2-fluid nozzle can be used. JP2002256458A describes an etching method using a 2-fluid nozzle. Thereafter, the etching resist is removed. A substantially cylindrical metal post is formed (FIG. 6D). The substantially cylindrical metal post is immersed in an etching solution. The etching solution is, for example, a cupric chloride etching solution. An upper surface and a side surface of the substantially cylindrical metal post are etched. The upper surface of the substantially cylindrical metal post is a surface on an opposite side of the support film. The side surface close to the upper surface is more easily etched than the side surface close to the support film. Therefore, the side surface of the metal post has a shape as illustrated in FIG. 4C. The metal post 77 having the upper surface (UF) and the lower surface (BF) that is on an opposite side of the upper surface (UF) is formed on the support film. The lower surface of the metal post is bonded to the support film. The support film is removed. The metal post having the shape illustrated in FIG. 4C is manufactured. For example, by using a method described in JP6057453A, a metal post having a shape illustrated in FIG. 4C may be manufactured. Thereafter, a metal film can be formed on the surface of the metal post by barrel plating.

The lower substrate of the first embodiment has the metal post 77, which is manufactured separately from the printed wiring board, on the pad (710FP). The metal post is mounter on the pad (710FP) using a mounter. Thereafter, by reflow and the like, the metal post is bounded to the pad (710FP) by the first joining member (16P). In the first embodiment, the metal post is manufactured separately from the printed wiring board 10. For example, the metal post is formed from a metal foil. Since the metal post is manufactured from the metal foil, variation in the heights of the metal posts of the first embodiment is small. Therefore, yield of mounting the upper substrate on the lower substrate 10 via the metal posts is high. The lower substrate 10 that allows for easy mounting can be provided. When the variation in the heights of the metal posts is large, a stress is likely to concentrate on a particular metal post and thus the connection reliability is low. However, in the first embodiment, the variation in the heights of the metal posts is small. Therefore, the connection reliability between the upper substrate and the lower substrate is high.

The diameter (d2) of the metal post that is formed separately from the printed wiring board is smaller than the diameter (d3) of the pad. Therefore, even when the pitch (p1) decreases, the spacing distance between adjacent metal posts can be increased. In the first embodiment, the pitch (p1) can be reduced. Since the spacing distance between adjacent metal posts is large, even when the pitch (p1) is 0.3 mm or less, the insulation reliability between the metal posts is high. When the pitch (p1) is 0.25 mm or less, the metal post becomes thin. In order to increase the connection reliability, it is preferable that an aspect ratio (h1/d2) of the metal post is 1.5 or more. When the number of the pads (710FP) is increased, the size of the printed wiring board is increased. However, when the aspect ratio (h1/d2) of the metal post is 2 or more, a stress caused by a difference between a physical property of the upper substrate and a physical property of the lower substrate is relaxed by the metal post. When h1/d2 exceeds 3.5, the metal post deteriorates in a heat cycle. Examples of physical properties include thermal expansion coefficient and Young's modulus. As illustrated in FIGS. 15B and 15D, when the metal post has a constricted portion, the stress relaxation effect is increased.

As illustrated in FIG. 1, the lower substrate 10 and the upper substrate 110 are connected by the metal post 77 that has high rigidity, and the joining members (16P, 112) that sandwich the metal post 77. It is preferable that the joining members are solders. The joining members have a rigidity lower than that of the metal post. A thermal stress between the upper substrate and the lower substrate is relaxed by the joining members. Strength of the printed wiring board that has the upper substrate and the lower substrate is maintained by the metal post. Warpage of the printed wiring board due to a difference between a physical property of the upper substrate and a physical property of the lower substrate is reduced.

In the first embodiment, the metal post is formed from a metal foil. Then, the metal post is mounted on the pad by reflow, ultrasound, or the like. Therefore, the manufacturing method is simplified.

FIG. 6 illustrates a method for manufacturing the metal post using an etching method.

(1) A support film 12 is prepared (FIG. 6A). The support film is formed by a based film and a bonding layer, the based film having a first surface (FF) and a second surface (SS) that is on an opposite side of the first surface, the bonding layer being formed on the first surface of the base film. As the support film, for example, a high heat resistant adhesive tape 9079 manufactured by Sumitomo 3M Ltd. can be used.

(2) A metal layer 14 such as a metal foil (copper foil) of 0.1 mm is laminated on the bonding layer of the support film 12 (FIG. 6B). The thickness of the metal layer is selected according to the height of the metal post 77. It is preferable that the metal layer is a copper foil or a copper alloy foil. In the first embodiment, the copper foil is used.

(3) An etching resist 18 is formed on the metal layer 14 (FIG. 6C). Each plating resist 18 has a cylindrical shape.

(5) The metal layer illustrated in FIG. 6C is immersed in an etching solution. When the metal layer is a copper foil, the etching solution is a cupric chloride etching solution. The metal layer 14 that is exposed from the etching resist 18 is removed (FIG. 6E). Composition of the etching solution is described, for example, in JP2001262373A. Since the etching solution stagnates under the etching resist, the metal layer 14 immediately below the etching resist is hard to be etched. Therefore, the side surface of the metal post is curved. The thinnest portion (NP) between the upper surface (UF) and the lower surface (BF) of the metal post is formed (FIG. 6E). Since the metal post is formed by removing the metal foil that is exposed from the etching resist, the metal post has the thin portion between the upper surface and the lower surface (FIG. 4B). The side surface of the metal post is curved. A surface of the metal post that opposes the support film is the lower surface. The metal post is formed by etching from the upper surface side of the metal post. The difference between the diameter (d1) of the upper surface and the diameter (d2) of the lower surface of the metal post can be increased by reducing an etching speed. Further, the diameter of the thinnest portion is reduced. The etching resist 18 is removed (FIG. 6F). The support film is removed. The metal post (77P) is formed (FIG. 4B).

A metal film is formed on the upper surface, the lower surface and the side surface of the metal post by barrel plating. The metal film is a Sn film or a Ni/Au film. The Ni/Au film is formed by a Ni film on the metal post and a Au film on the Ni film.

Next, a method for bonding the metal post 77 to the wiring board 101 is described.

FIG. 2 illustrates a partially processed lower substrate (wiring board) 101. The solder bump (76F) is formed on the pad (710FI). An electronic part such as an IC chip is mounted on the wiring board via the solder bump (76F). The solder bump (760F) is formed on the pad (710FP). The solder bump (760F) is the first joining member such as the first solder. The metal post (77P) is mounted on the wiring board via the solder bump (760F). The first joining member has a melting point higher than that of the solder bump (76F) of the first pad (710FI). First, the melting point of the first joining member (760F) is higher than a melting point of the second joining member for connecting the metal post and the upper substrate. As a result, the metal post does not come off from the lower substrate due to heat.

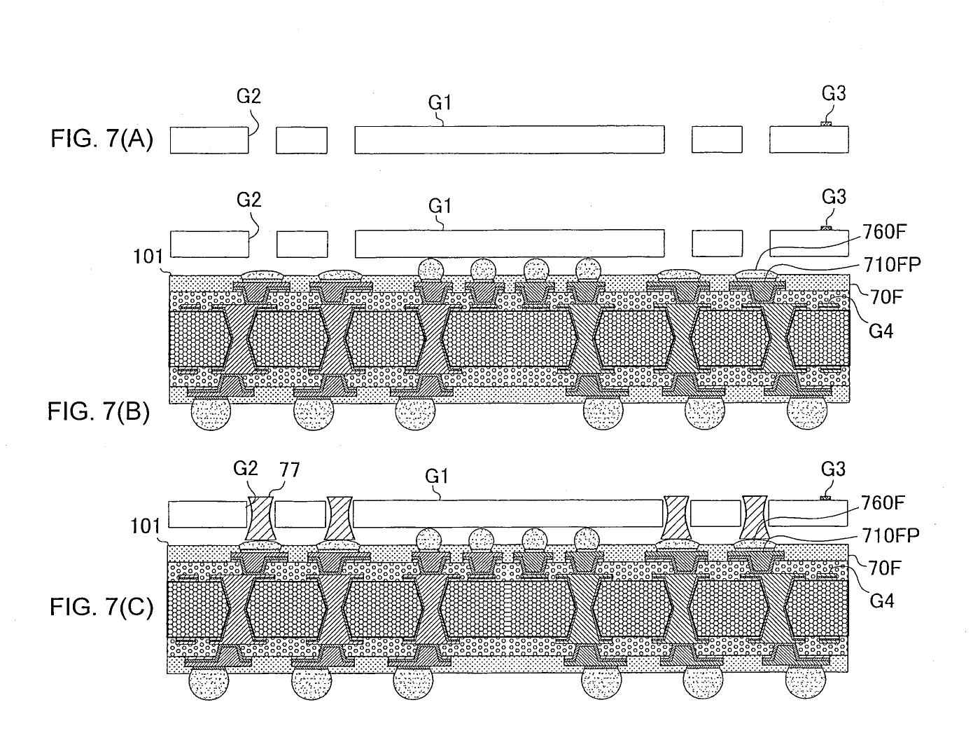

A jig (G1) for mounting the metal post is prepared (FIG. 7A). The jig has through holes (G2). The through holes (G2) and the pads (710FP) are arranged in one-to-one correspondence. By using an alignment mark (G3) of the jig and an alignment mark (G4) of the wiring board, the jig (G1) and the wiring board 101 are aligned (FIG. 7B). The through holes (G2) are respectively positioned on the pads (710FP). Next, by using a mounter or the like, the metal posts 77 are respectively inserted into the through holes (G2) (FIG. 7C). The metal posts 77 are respectively placed on the solder bumps (760F).

The jig and the metal posts 77 are placed on the wiring board. In this state, reflow is performed. By the reflow, the metal posts are bonded to the solder bumps (760F). The metal posts are bonded to the wiring board. Next, the jig is removed from the wiring board. The lower substrate (first printed wiring board) 10 is completed (FIG. 4A).

An electrode 92 of the IC chip 90 is connected to the first pad (710FI) of the first printed wiring board via the solder bump (76F). The IC chip 90 is mounted on the printed wiring board 10.

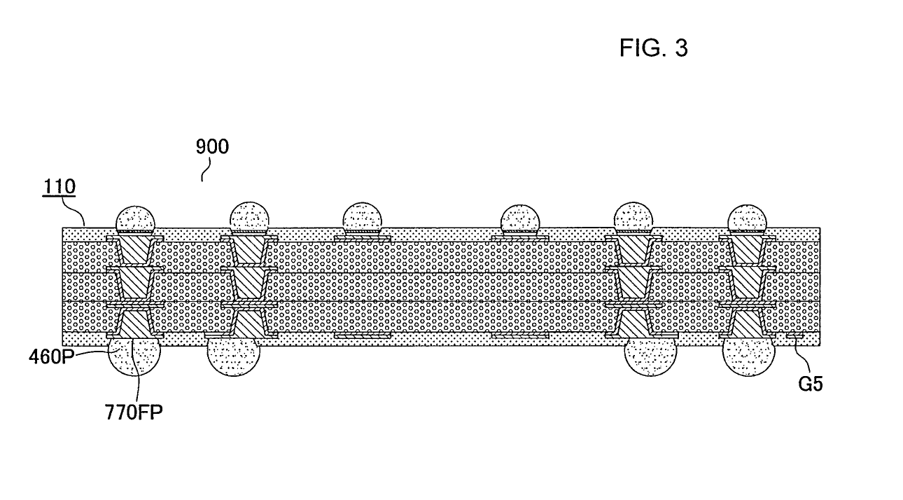

The upper substrate 110 is prepared (FIG. 3). The upper substrate has a pad (770FP) for connecting to the metal post 77. A solder bump 460P for connecting to the metal post is formed on the pad (770FP). The pad (710FP) of the lower substrate and the pad (770FP) of the upper substrate are aligned and the upper substrate is placed on the lower substrate. The lower substrate has the alignment mark (G4) that is made at the same time as the pad (710FP), and the upper substrate has an alignment mark (G5) that is made at the same time as the pad (770FP). These alignment marks are used for the alignment.

Thereafter, by reflow, the upper substrate 110 is bonded to the metal post 77 via the solder bump (460P). The upper substrate is mounted on the lower substrate 10 (FIG. 1). The printed wiring board 1000 is completed. FIG. 1 illustrates an application example of the printed wiring board 1000. In the application example, the lower substrate, the IC chip 90 on the lower substrate, the upper substrate, and the memory 900 on the upper substrate are formed. The second joining member 112 such as the second solder is formed from the solder bump (460P) that is formed on the second substrate.

During reflow, the solder 460P wetly spreads to the side surface of the metal post 77. However, in the embodiment, the side surface of the metal post is curved. The height HS of the joining member (solder) on the side surface of the metal post is lowered. When the metal post has the thinnest portion (NP), the solder is likely to gather on the thinnest portion (NP) of the metal post. The height (HS) of the second joining member (second solder) on the side surface of the metal post is lowered.

The joining member such as the solder wetly spreads from the upper surface of the metal post toward the lower surface. Therefore, a majority of the solder is likely to exist on the upper surface side of the metal post. For example, when the lower substrate has the metal post illustrated in FIGS. 4C and 15C, a majority of the solder exists on the thin portion of an upper side of the metal post. Therefore, the height (HS) of the solder on the side surface of the metal post is lowered.

The insulation reliability between adjacent metal posts is increased. Short-circuiting between the adjacent metal posts via the solder does not occur.

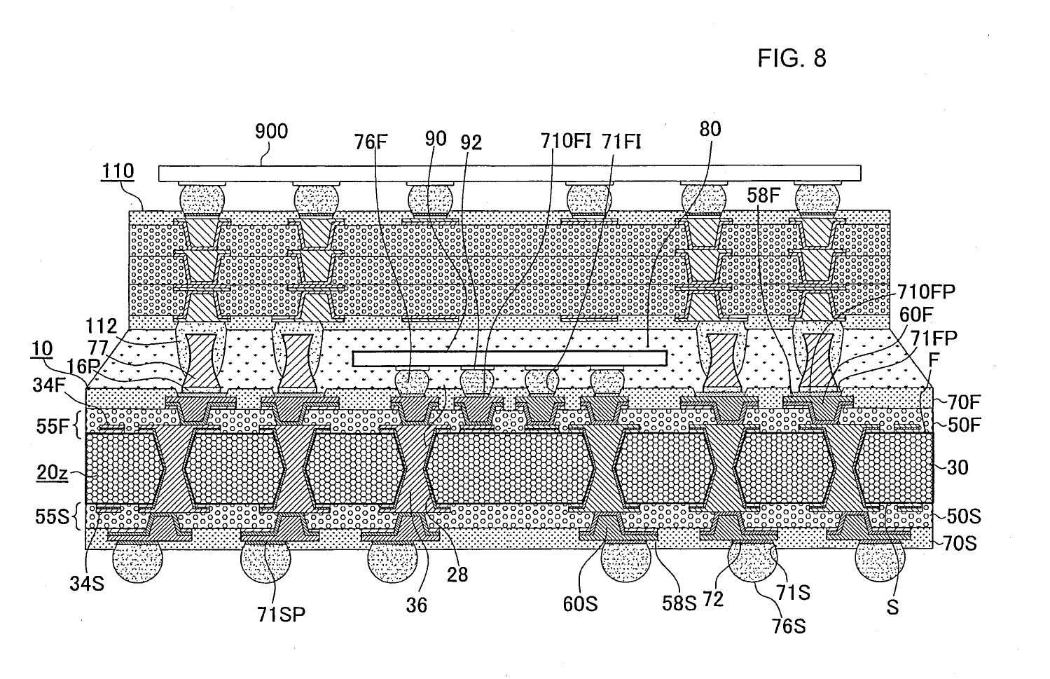

A mold resin 80 is filled between the lower substrate 10 and the upper substrate 110 (FIG. 8).

### Second Embodiment

Another method for manufacturing a metal post is described below. In the first embodiment, the metal post is manufactured separately from the lower substrate. In a second embodiment, a metal post is formed on a lower substrate. In the first embodiment and the second embodiment, the method for manufacturing a metal post is different. However, other aspects are the same in the first embodiment and the second embodiment.

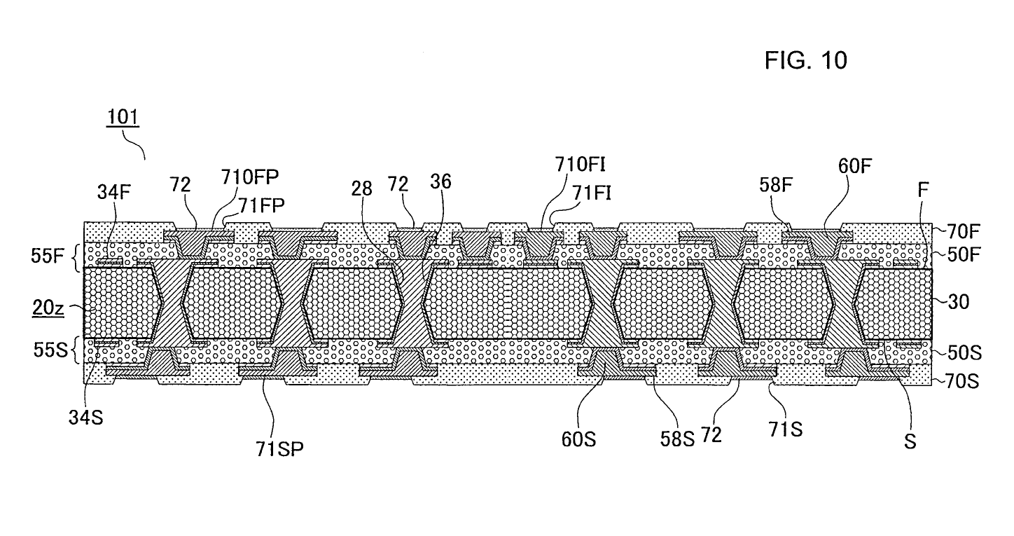

FIGS. 10 and 15-19 illustrate a method for manufacturing a metal post.

A wiring board 101 illustrated in FIG. 10 is prepared in the same way as in the first embodiment. The wiring board is manufactured, for example, using a method described in JP2007227512A. The wiring board 101 has an uppermost interlayer resin insulating layer 50F, a pad (first pad) (710FI) for mounting an electronic part such as an IC chip on the uppermost interlayer resin insulating layer (50F), and a pad (second pad) (710FP) for mounting an upper substrate 110. Further, the wiring board 101 has an upper side solder resist layer (70F) on top of the uppermost interlayer resin insulating layer, the first pad and the second pad. The upper side solder resist layer has a first opening (71FI) for exposing the first pad and a second opening (71FP) for exposing the second pad. A protective film 72 is formed on the first pad. The protective film is formed by a Ni layer on the pad and Au layer on the Ni layer. A protective film is similarly formed on the second pad.

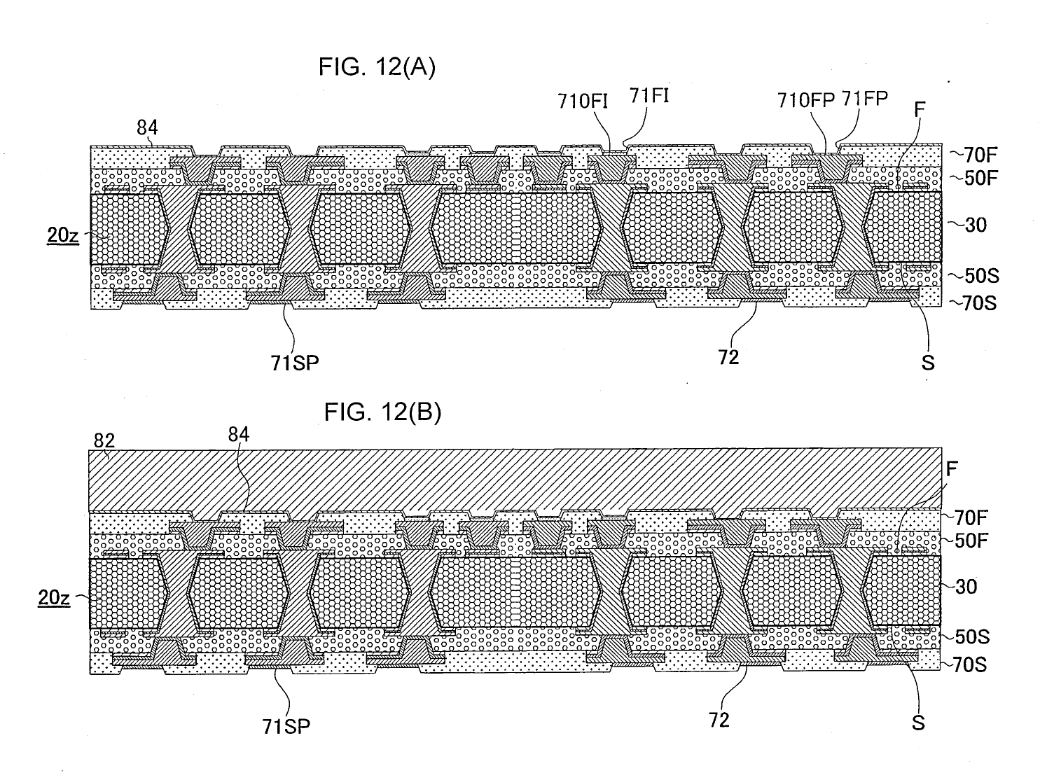

A PET film is affixed to a lower side solder resist layer (70S) and a pad (71SP). The PET film is not illustrated in the drawings. A seed layer 84 is formed on the upper side solder resist layer (70F), inside the first opening (FI) and inside the second opening (71FP) of the wiring board 101 (FIG. 12A). The seed layer is formed by electroless plating or sputtering. From a viewpoint of adhesion between the solder resist layer and the seed layer, it is preferable that the seed layer is formed by sputtering. As a sputtering film, nickel is preferred. The seed layer is hard to peel off from the solder resist layer.

An electrolytic plating film 82 is formed on the seed layer 84 (FIG. 12B). As the electrolytic plating film 82, an electrolytic copper plating film is preferred.

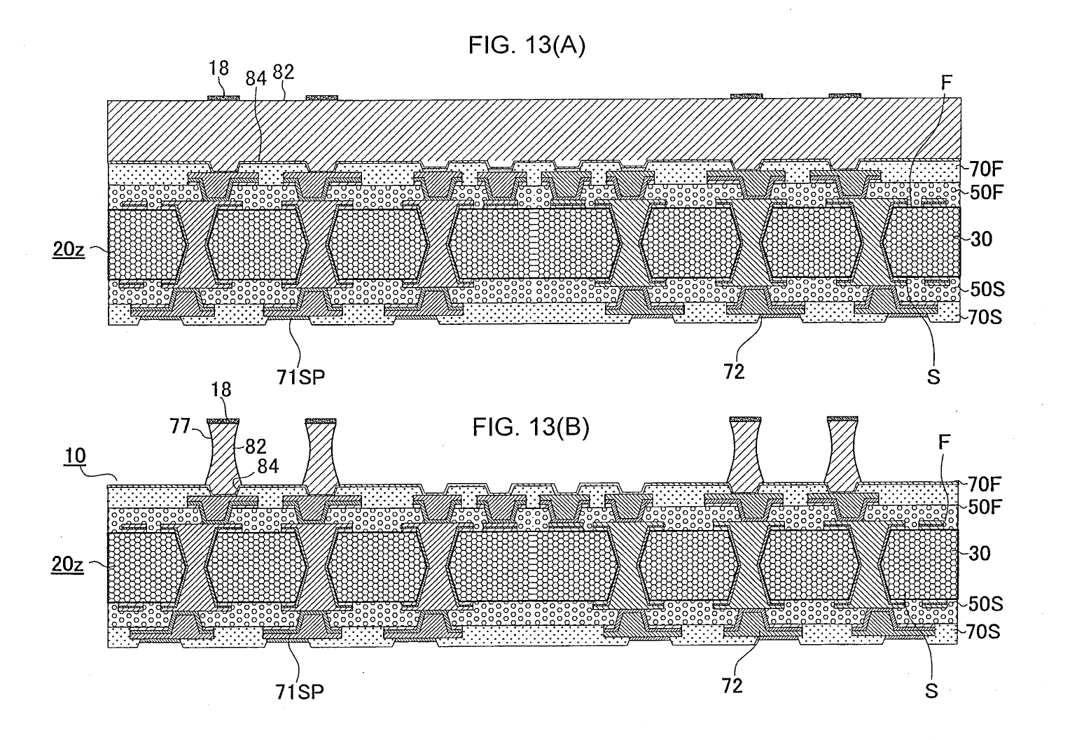

Based on an alignment mark for forming the second opening (71FP), an etching resist 18 as an etching mask is formed on the electrolytic plating film 82 (FIG. 13A). The alignment mark for forming the second opening (71FP) is formed at the same time as the second pad. The etching resist 18 is formed on the second pad.

The electrolytic copper plating film 82 that is exposed from the etching resist is removed by selective etching (FIG. 13B). The electrolytic plating film 82 other than the electrolytic copper plating film on the second pad is removed. As an etching solution, an SF-5420 manufactured by MEC Co. Ltd. can be used.

The etching method that is adopted in the first embodiment for manufacturing the metal post is used in the method for manufacturing the metal post of the second embodiment. Therefore, the metal post of the second embodiment has a shape same as that of the metal post of the first embodiment. The metal post of the second embodiment is formed by plating. The side surface of the metal post of the second embodiment has a shape as illustrated in FIGS. 4B, 4C and 15B-15D. The side surface is curved. Therefore, the metal post of the second embodiment has the same effect as the first embodiment.

The seed layer that is formed of Ni is exposed. The electrolytic plating film and the seed layer are not removed at the same time and thus the first pad is hardly damaged.

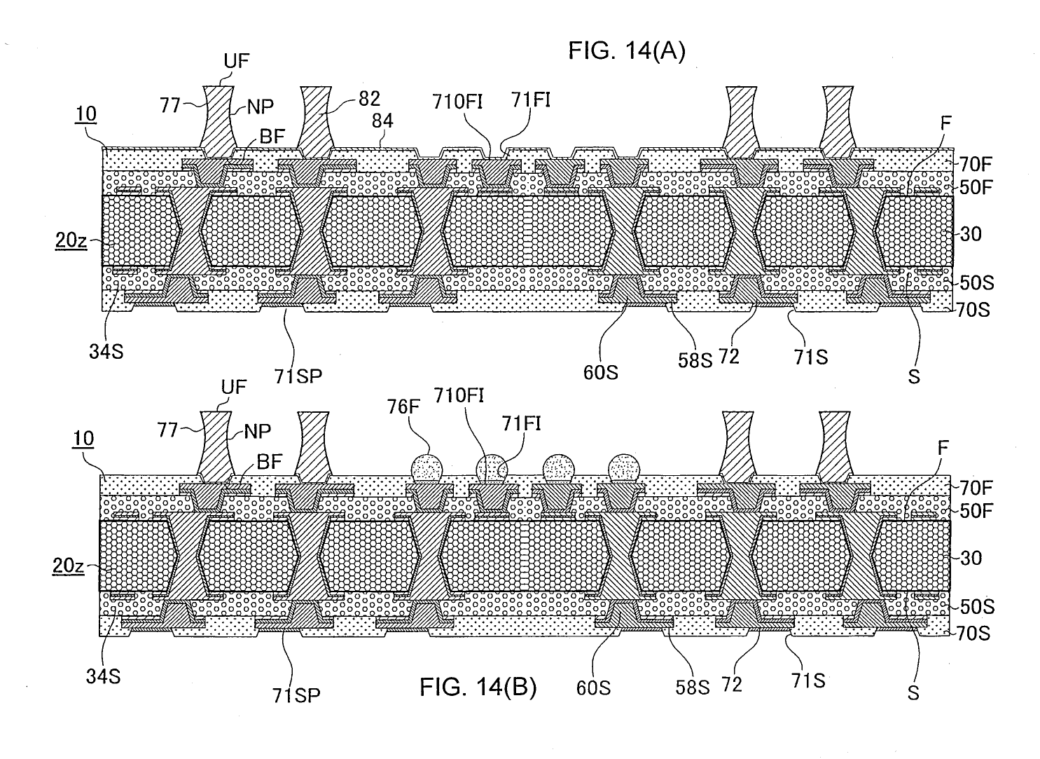

The etching resist 18 is removed (FIG. 14A).

Next, the seed layer 84 that is formed of nickel and is exposed from the electrolytic plating film 82 on the second pad is removed by selective etching (FIG. 14B). As an etching solution, an NH-1860 manufactured by MEC Co. Ltd. can be used.

However, when a protective film containing a metal other than copper is formed on the first pad, the seed layer may be formed of copper. Examples of the metal other than copper include Au, Pd, Ag and Ni. When a protective film containing at least one of these metals is formed, the seed layer and the electrolytic plating may be formed of copper. Resistance of the metal post is lowered. By selectively etching the electrolytic plating film and the seed layer that are formed of copper, the first pad is hardly damaged. As a selective etching solution of copper, an SF-5420 manufactured by MEC Co. Ltd. can be used. The electrolytic plating film and the seed layer are removed at the same time. The electrolytic plating film and the seed layer are removed in one process.

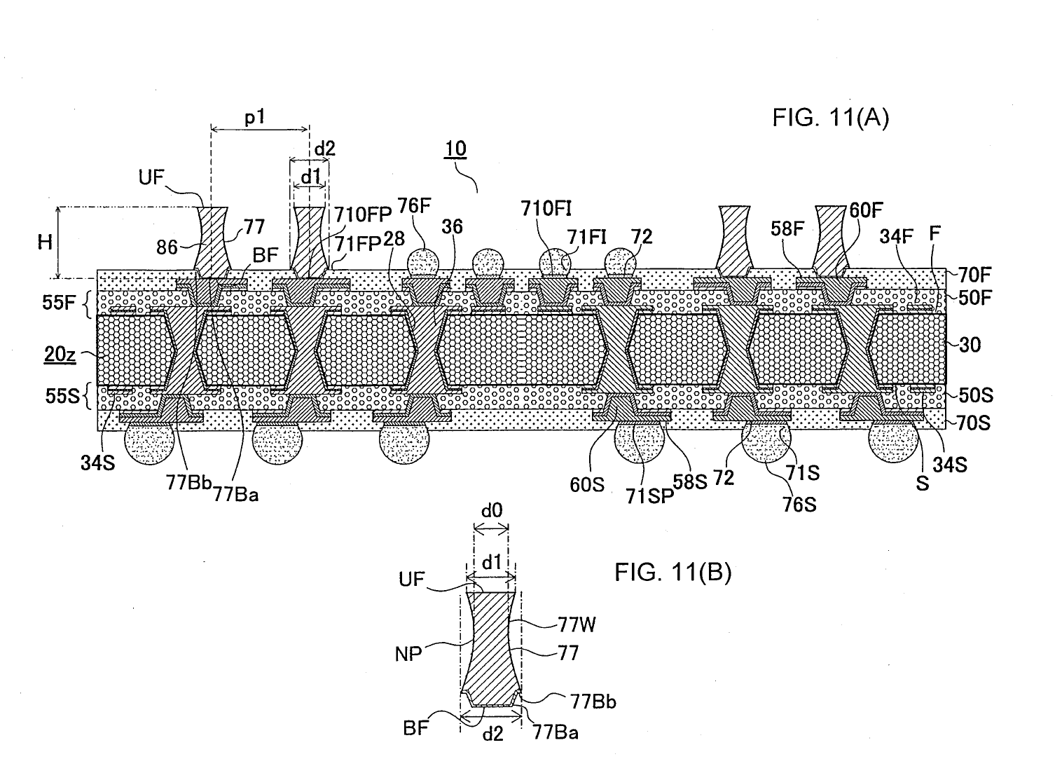

Solder bumps (76F, 76S) are formed on the first pad (710FI) and the pad (71SP). The lower substrate 10 having the solder bumps (76F, 71S) is completed (FIG. 11A).

FIG. 11B illustrates an example of the metal post 77 of the second embodiment.

Thereafter, similar to the first embodiment, an upper substrate is prepared, and the upper substrate is mounted on the lower substrate. A mold resin is filled between the upper substrate and the lower substrate.

As an electronic part such as an IC chip that is mounted on a printed wiring board becomes sophisticated, the number of I/O's is increasing. Therefore, a pitch between metal posts becomes narrower. In a case of a cylindrical metal post, when a solder is formed on the upper surface and the side surface of the metal post, and when a pitch between metal posts is narrowed, short-circuiting may occur between adjacent metal posts due to the solder on the metal posts.

According to an embodiment of the present invention, a pitch between metal posts that are for mounting a second printed wiring board is narrowed. According to another embodiment of the present invention, insulation reliability between the metal posts can be ensured even when the pitch between the metal posts is narrowed. According to yet another embodiment of the present invention, connection reliability between a first printed wiring board and a second printed wiring board in a printed wiring board that is formed by the first printed wiring board and the second printed wiring board can be improved, the first printed wiring board having a metal post and the second printed wiring board being mounted via the metal post on the first printed wiring board.

A first printed wiring board according to an embodiment of the present invention has a wiring board and metal posts that are formed on the wiring board and mount a second printed wiring board. The metal posts have lower surfaces connecting to the wiring board, upper surfaces for connecting to the second printed wiring board, and side surfaces between the upper surfaces and the lower surfaces. The side surfaces of the metal posts are curved.

A printed wiring board according to an embodiment of the present invention has: a first printed wiring board that has a wiring board and metal posts that are formed on the wiring board and mount a second printed wiring board; second joining members that are formed on the metal posts; and the second printed wiring board that is mounted on the first printed wiring board. The metal posts have lower surfaces connecting to the wiring board, upper surface connecting to the second printed wiring board, and side surfaces between the upper surfaces and the lower surfaces. The side surfaces of the metal posts are curved. The second joining members are formed on the upper surfaces of the metal posts and the side surfaces of the metal posts. The metal posts and the second printed wiring board are connected by the second joining members.

A method for manufacturing a first printed wiring board according to an embodiment of the present invention includes: forming a metal layer on a support film; forming an etching mask on the metal layer; forming metal posts that have curved side surfaces by removing the metal layer that is exposed from the etching mask by etching; removing the etching mask from the metal posts; removing the support film; preparing a wiring board; and mounting the metal posts on the wiring board.

A method for manufacturing a first printed wiring board according to another embodiment of the present invention includes: preparing a wiring board; forming a seed layer on the wiring board; forming an electrolytic plating layer on the seed layer; forming an etching mask on the electrolytic plating layer; and forming metal posts that have a curved side surfaces on the wiring board by etching the electrolytic plating layer that is exposed from the etching mask.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a wiring board; and
a plurality of metal posts formed on the wiring board and positioned to mount a second printed wiring board onto the wiring board,
wherein each of the metal posts has a first surface connected to the wiring board, a second surface configured to connect the second printed wiring board, and a side surface between the first surface and the second surface, and the side surface of each of the metal posts forms a curved surface.

2. A printed wiring board according to claim 1, wherein each of the metal posts has a thinnest portion between the first surface and the second surface.

3. A printed wiring board according to claim 1, further comprising:
a plurality of second joining portions formed on the plurality of meal posts such that each of the second joining portions connects the second printed wiring board and the second surface of each of the metal posts,
wherein each of the second joining portions is formed on the second surface and side surface of each of the metal posts.

4. A printed wiring board according to claim 3, further comprising:
a plurality of first joining portions formed on the plurality of meal posts such that each of the first joining portions connects the wiring board and the first surface of each of the metal posts,
wherein the plurality of first joining portions is made of a material which is different from a material of the plurality of second joining portions.

5. A printed wiring board according to claim 3, further comprising:
the second printed wiring board mounted on the wiring board through the plurality of metal posts.

6. A printed wiring board according to claim 1, wherein the plurality of metal posts comprises a plating material.

7. A printed wiring board according to claim 1, wherein the second surface of each of the metal posts has a diameter which is smaller than a diameter of the first surface of each of the metal posts.

8. A printed wiring board according to claim 1, further comprising:
a plurality of first joining portions formed on the plurality of meal posts such that each of the first joining portions connects the wiring board and the first surface of each of the metal posts.

9. A method for manufacturing a printed wiring board, comprising:
forming a metal layer on a support film;
forming an etching mask on the metal layer;
etching a portion of the metal layer exposed from the etching mask such that the portion of the metal layer is removed and a plurality of metal posts each having a curved side surface is formed;
removing the etching mask remaining on the plurality of metal posts;
removing the support film from the plurality of metal posts; and
mounting the plurality of metal posts on a wiring board such that the plurality of metal posts is positioned to mount a second printed wiring board onto the wiring board.

10. A method for manufacturing a printed wiring board according to claim 9, wherein the etching of the portion of the metal layer includes forming a thinnest portion between a first surface and a second surface of each of the metal posts.

11. A method for manufacturing a printed wiring board according to claim 9, further comprising:
forming a plurality of second joining portions on the plurality of meal posts such that each of the second joining portions connects the second printed wiring board and a second surface of each of the metal posts,
wherein each of the second joining portions is formed on the second surface and a side surface of each of the metal posts.

12. A method for manufacturing a printed wiring board according to claim 11, further comprising:
forming a plurality of first joining portions formed on the plurality of meal posts such that each of the first joining portions connects the wiring board and a first surface of each of the metal posts,
wherein the plurality of first joining portions is made of a material which is different from a material of the plurality of second joining portions.

13. A method for manufacturing a printed wiring board according to claim 11, further comprising:
mounting the second printed wiring board on the wiring board through the plurality of metal posts.

14. A method for manufacturing a printed wiring board according to claim 9, wherein the plurality of metal posts comprises a plating material.

15. A method for manufacturing a printed wiring board, comprising:
forming a seed layer on a wiring board;
forming an electrolytic plating layer on the seed layer;
forming an etching mask on the electrolytic plating layer; and
etching a portion of the electrolytic plating layer exposed from the etching mask such that the portion of the electrolytic plating layer is removed and a plurality of metal posts each having a curved side surface is formed on the wiring board such that the plurality of metal posts is positioned to mount a second printed wiring board onto the wiring board.

16. A method for manufacturing a printed wiring board according to claim 15, wherein the etching of the portion of the electrolytic plating layer includes forming a thinnest portion between a first surface and a second surface of each of the metal posts.

17. A method for manufacturing a printed wiring board according to claim 15, further comprising:
forming a plurality of second joining portions on the plurality of meal posts such that each of the second joining portions connects the second printed wiring board and a second surface of each of the metal posts,
wherein each of the second joining portions is formed on the second surface and a side surface of each of the metal posts.

18. A method for manufacturing a printed wiring board according to claim 17, further comprising:
forming a plurality of first joining portions formed on the plurality of meal posts such that each of the first joining portions connects the wiring board and a first surface of each of the metal posts,
wherein the plurality of first joining portions is made of a material which is different from a material of the plurality of second joining portions.

19. A method for manufacturing a printed wiring board according to claim 15, further comprising:
mounting the second printed wiring board on the wiring board through the plurality of metal posts.

20. A method for manufacturing a printed wiring board according to claim 15, wherein the etching of the portion of the electrolytic plating layer includes forming a second surface of each of the metal posts having a diameter which is smaller than a diameter of a first surface of each of the metal posts.
